(19) United States
(12) Patent Application Publication
(10) Pub. No.: US 2025/0220926 A1
(43) Pub. Date: Jul. 3, 2025

(54) HIGH BANDWIDTH MEMORY CUBE

(71) Applicant: International Business Machines Corporation, Armonk, NY (US)

(72) Inventors: John W. Golz, Hopewell Junction, NY (US); John Knickerbocker, Monroe, NY (US); Mukta Ghate Farooq, Hopewell Junction, NY (US); Keiji Matsumoto, Yokohama-shi (JP)

(21) Appl. No.: 18/398,568

(22) Filed: Dec. 28, 2023

(51) Int. Cl. H10B 80/00; H01L 25/00; H01L 25/065; H01L 25/18

(52) U.S. Cl. CPC H10B 80/00; H01L 25/0652; H01L 25/18; H01L 25/50; H01L 2225/06513; H01L 2225/06551; H01L 2225/06572; H01L 2225/06589

(57) ABSTRACT

A high bandwidth 3D memory cube structure having one or more passive chip structures such as a glass chip, a dielectric oxide chip or a Si chip having a thick conductive wiring formed thereon that is dedicated for routing power signals for improved power delivery. The non-semiconductor passive chip or Si chip having a thick wiring fabricated thereon is dedicated for routing power signals to another component connected to the high bandwidth memory cube such as a voltage step-down circuit or like power management device, a processing logic device, or an interposer. The voltage step down circuit can interfaces with the memory cube structure at a top edge thereof. The provision of a glass or a Si substrate with thick wiring and voltage step down circuitry in the high bandwidth 3D memory cube structure, solves power management challenges and enables customization of standard DRAM, fixed wiring and I/O footprint.

### BACKGROUND

This disclosure relates generally to semiconductor devices, and more specifically to high bandwidth memory systems or memory units, and further to a novel high bandwidth memory cube structure and method of operation to provide power management features in cube memory chips.

In current high bandwidth 3D memory cube structures that include plural memory chips or slices that are mated with circuitry of another device, e.g., a transversely oriented logic chip or like processing device, each memory slice includes thin wiring, e.g., 10 microns or less, through which power signals are routed through the memory chips to the logic chip or device.

As a consequence, in such a configuration of current memory cube memory chip structures, power delivery to a logic element is challenging because of the thin wiring on memory chips currently used to route power signals to other devices. The thin wiring can cause egregious I²R power loss of routed power signals through the wiring patterns on each of the vertically-oriented memory slices for delivery to any connected logic device or element.

### SUMMARY

Embodiments of the present disclosure provide for a high bandwidth 3D memory cube structure having one or more passive chip structures such as a glass chip, a dielectric oxide chip or a Si chip having a thick conductive wire element formed thereon that is dedicated for routing power signals for improved power delivery.

In an aspect, the semiconductor passive chip structure includes a non-semiconductor passive chip or Si chip having a thick wiring fabricated thereon that is dedicated for routing power signals to another component connected to the high bandwidth memory cube.

Further to this aspect, the another component connected to the high bandwidth memory cube is a power management device, a processing logic device, or an interposer.

In an aspect, the power management device is a voltage step down circuit interfacing with the memory cube structure at a top edge thereof.

Additionally, the non-semiconductor passive chip or a passive or active Si chip having a thick wire for improved power delivery can be further contained with decoupling capacitors (“decaps”), inductors and voltage regulators.

According to an aspect of the present disclosure, there is provided an apparatus comprising: a plurality of vertically-oriented semiconductor memory slices, each semiconductor memory slice having one or more memory elements disposed thereon for storing data; one or more vertically-oriented passive slices having a conductive wire element disposed thereon for delivering power signals from a power source, the plurality of vertically-oriented semiconductor memory slices and one or more vertically-oriented passive slices forming a stack; and a logic chip disposed on top of the stack and oriented perpendicular to the plurality of vertically-oriented semiconductor memory slices and one or more vertically-oriented non-semiconductor passive slices, the logic chip having circuitry configured to process data from a semiconductor memory slice, where the wiring element delivers power signals to the logic chip circuitry.

According to a further aspect, there is provided an apparatus comprising: a stacked structure comprising a plurality of vertically-oriented semiconductor memory slices, each semiconductor memory slice having one or more memory elements disposed thereon for storing data and a plurality of vertically-oriented passive slices having a conductive wire element disposed thereon for delivering power signals from a power source; a voltage step down chip disposed on top of the stack and oriented perpendicular to the plurality of vertically-oriented semiconductor memory slices and vertically-oriented non-semiconductor passive slices for modifying one or more of: a voltage level, a current level or both a voltage and current level of a power signal received via the conductive wire element signal; and a logic chip disposed on top of the voltage step down chip and in electrical communication therewith and having circuitry configured to process data from a semiconductor memory slice, where the wiring element delivers modified power signals to the logic chip circuitry.

According to yet another aspect, there is provided a method of forming a stacked memory structure. The method comprises: providing one or more active or passive substrates having a memory die formed thereon; providing one or more passive substrates having a wire element formed thereon, the wire element extending from a bottom edge to a top edge of the passive substrate for delivering power signals; stacking an arrangement of the active or passive substrates having a memory die thereon and passive substrates having a wire element formed thereon; bonding the stacked arrangement of substrates and dies by hybrid bonding or thermal compression bonding; planarizing a lateral surface of stacked dies; forming under-bump metallization on the planarized lateral surface in alignment with an edge of the wire element; bonding the stacked bonded stacked arrangement of substrates and dies to a substrate; and dispensing an underfill material for packaging the stacked memory structure.

Further features, as well as the structure and operation of various embodiments, are described in detail below with reference to the accompanying drawings. In the drawings, like reference numbers indicate identical or functionally similar elements.

### BRIEF DESCRIPTION OF THE DRAWINGS

FIG. 1 diagrammatically illustrates a 3D chip stack or 3D logic memory cube consisting of a multiple vertically oriented (Y-axis) memory dies or slices according to a conventional implementation;

FIG. 2 diagrammatically illustrates a 3D chip stack or 3D logic memory cube according to an embodiment of the present disclosure;

FIG. 2A shows a cross-sectional view of a single passive chip taken along line A-A of FIG. 2 and showing a configuration of a slice along a Z-axis direction;

FIG. 2B shows a cross-sectional view of the passive chip taken along line B-B of FIG. 2;

FIGS. 3A-3D depict detailed cross-sectional views of an edge of a non-semiconductor passive chip or a passive or active Si chip for power delivery according to an embodiment shown in FIG. 2;

FIG. 4 shows an alternate embodiment of a single vertically oriented memory chip or memory slice, e.g., a glass, an oxide or a silicon chip, including thick wire conductor connecting from bottom logic die to an edge connector at a top edge of the chip;

FIG. 5 shows a cross-sectional view of a high bandwidth memory cube for high-end servers and mobile/edge computing and other high-end applications; and

FIGS. 6A-6H depicts an exemplary process for fabricating a 3D high-bandwidth memory cube according to embodiments herein.

### DETAILED DESCRIPTION

According to an aspect of the invention, there is provided an apparatus having a plurality of vertically oriented semiconductor memory slices, each semiconductor memory slice having one or more memory elements disposed thereon for storing data. The apparatus further includes one or more vertically oriented passive slices having a conductive wire element disposed thereon for delivering power signals from a power source. The plurality of vertically oriented semiconductor memory slices and one or more vertically oriented passive slices form a stack. The apparatus further includes a logic chip disposed on top of the stack and oriented perpendicular to the plurality of vertically oriented semiconductor memory slices and one or more vertically oriented non-semiconductor passive slices. The logic chip has circuitry configured to process data from a semiconductor memory slice, where the wiring element delivers power signals to the logic chip circuitry.

Advantageously, the apparatus including a stack implementing a glass chip or a Si chip with conductive wire element for power signal delivery ensures efficient power delivery in a high bandwidth memory cube and energy efficient computing.

In an aspect, in the apparatus, the passive slice comprises: a voltage step down circuit for modifying one or more of: a voltage level, a current level or both a voltage and current level of a received signal; a first thick wire extending from the conductive connection at a bottom edge of the non-semiconductor passive slice to the voltage step down circuit for receipt of power signals thereat; and a second shorter wire extending from the voltage step down circuit to a conductive connector at the logic chip for delivery of modified power signals.

Alternatively, in the apparatus, the voltage step-down circuit is disposed on top of the stack and beneath the logic chip, the voltage step-down circuit oriented perpendicular to the plurality of vertically-oriented semiconductor memory slices and having circuitry for receiving a power signal from a vertically-oriented semiconductor memory slice and modifying one of: voltage level, a current level or both a voltage and current level, of the received power signal.

Advantageously, the apparatus including a stack implementing a glass chip or a Si chip with conductive wire element in addition to the voltage step-down circuit solves power management challenges of 3D cube memory chips and their ready integration in a high-performance chiplet/3D memory strategy.

Besides solving power management challenges, the non-semiconductor passive chips (e.g., glass chips, dielectric oxide chips) or Si chips with thick wiring used for power delivery enables customization of the memory, e.g., standard DRAM, fixed wiring, and fixed I/O footprint (e.g., for low cost, high volume products).

One or more of the following aspects or features can be separable or optional from each other in one or more embodiments.

In another aspect, the passive slices consist of a glass substrate or a dielectric oxide material substrate or a silicon-containing substrate with the thick wiring element for the power signal delivery and the semiconductor memory slices consist of a passive or active silicon-based (Si) integrated circuit chip, the passive or active silicon-based integrated circuit chip having no crack stop structure.

In this aspect, the passive or active silicon-based (Si) integrated circuit chip is sealed using a sealing dielectric material.

Further, the wiring element for delivering power extends from a conductive connection at a bottom edge of the passive slice to a conductive connection at a top edge of the passive slice.

Yet in another aspect, the passive slice further comprises a dummy mechanical die or a die with other circuitry.

Yet in another aspect, a size of the passive slice having the wiring element for delivering power signals is different in the X-axis dimension and/or Y-axis dimension and/or Z-axis dimension relative to a size of the semiconductor memory slices.

Advantageously, the size of the passive slice having the wiring element for delivering power signals results in a high bandwidth memory cube in small form factor (e.g., smaller, thinner), for many types of applications, e.g., mobile applications, edge computing and automotive applications.

Yet in another aspect, the non-semiconductor passive slice having the wiring element for delivering power signals further comprises one or more of embedded decoupling capacitors, inductors or voltage regulator devices.

Yet in another aspect, each non-semiconductor passive slice comprises a planarized edge surface exposing a surface of the wiring element, and an under-bump metal connection contacting the exposed surface of the wiring element.

Yet in another aspect, the apparatus consists of an alternating arrangement of vertically-oriented semiconductor memory slices and vertically-oriented non-semiconductor passive slices having the wire element disposed thereon.

Yet in another aspect, the apparatus consists of a further logic chip formed on the interposer structure, where the formed stack of the plurality of vertically-oriented semiconductor memory slices and one or more vertically-oriented passive slices having bottom edge connectors electrically connect to active devices of the further logic chip.

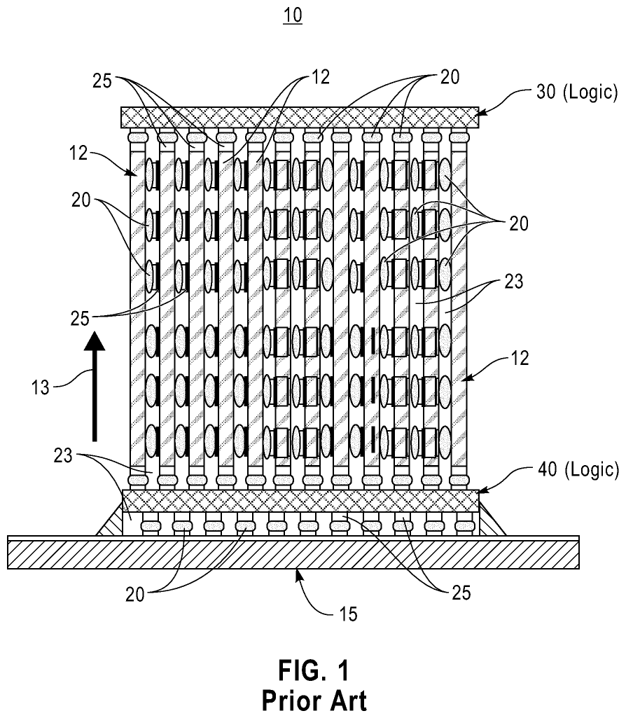

FIG. 1 diagrammatically illustrates a 3D chip stack or 3D logic memory cube 10 consisting of a horizontal (X-axis) series stack of multiple vertically-oriented (Y-axis) memory dies or slices 12, each slice 12 being a memory die including one or more memory chips with each chip having one or more memory banks each including one or more levels of circuitry, e.g., memory cells, transistors, etc. In an embodiment, the 3D logic memory cube 10 includes include a top element comprised of a top logic chip 30, e.g., containing switches, active devices, and logic circuits for processing data from memory dies or slices. In conventional designs, the top logic chip includes an active device surface, and the memory slices 12 are vertically aligned such that a surface of the memory slices is oriented perpendicular to the active device surface of the logic chip. A bottom element is a further logic die 40 containing switches and logic circuits for processing data and for providing power signals to be routed to the respective vertically oriented memory chips 12) and top logic die or chip 30. In an embodiment, the bottom logic die or chip 40 is formed on a substrate or chip-carrier 15. For example, the multiple semiconductor vertically oriented memory dies or slices 12 including memory chips is provided with edge connections, arranged as is well known in the technology, and adapted to be mounted on a substrate or chip carrier (or “interposer”) 15. In FIG. 1, individual dies of memory chips 12 are connectable to neighboring chips via conductive metal interconnect structures 20 (e.g., Pb/Sn solder bump, copper) so chips 12 may communicate to other chips 12. The interconnect further includes an under bump metallurgy 25 which is includes mechanical structures 25 to improve and strengthen the mechanical performance and increase strength of the electrical connection 20 interconnecting neighboring memory chip dies. Further disposed between adjacent chips 12 is an underfill material 23, e.g., an epoxy resin, applied to fill the gap between the vertically oriented chips chip and between the logic chip 40 and substrate to enhance mechanical stability and reliability. Similar conductive metal structures 20 and connecting underfill structures 25 are provided to improve and strengthen the mechanical performance and increase strength of the electrical connection interconnecting memory chip dies 12 to the top logic chip 30 and bottom logic chip 40. Reading and writing data to memory chips on memory dies 12 can be initiated at the top logic chip 30 or bottom logic chip 40 in communication with each memory slice or die 12.

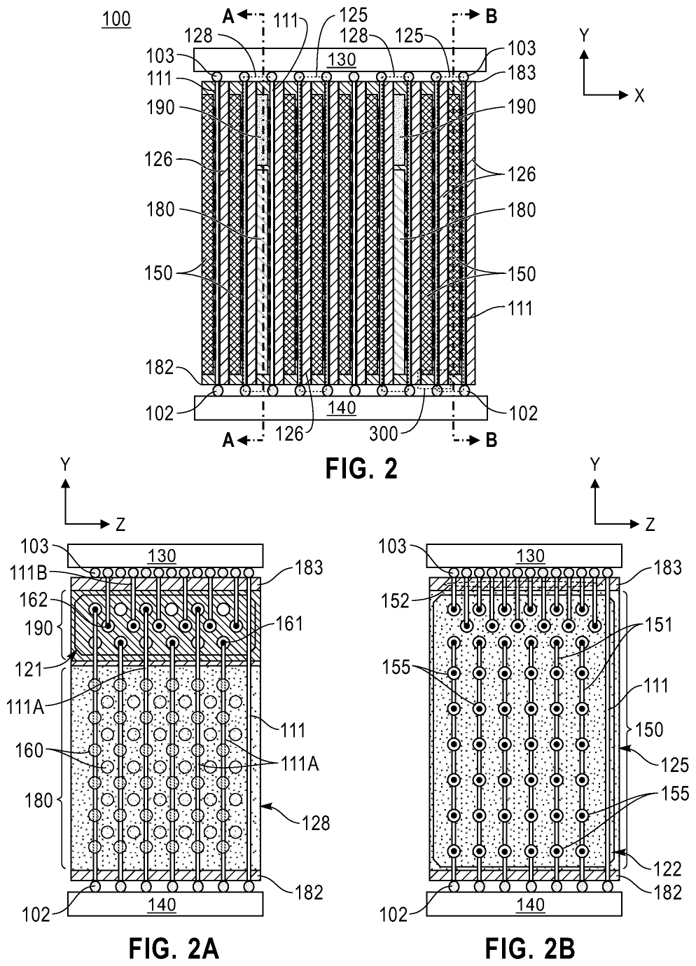

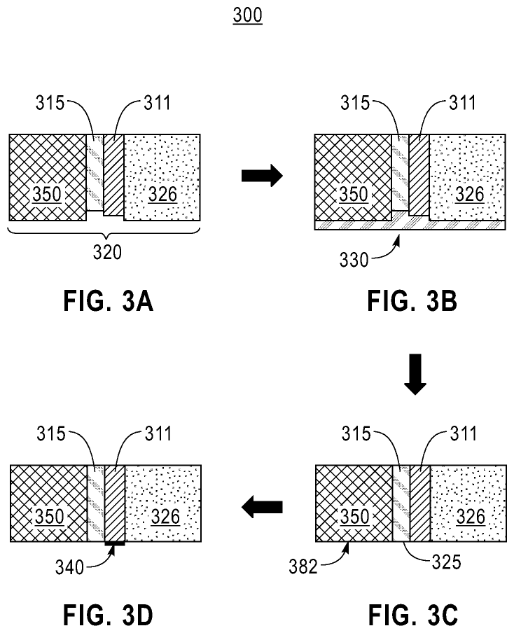

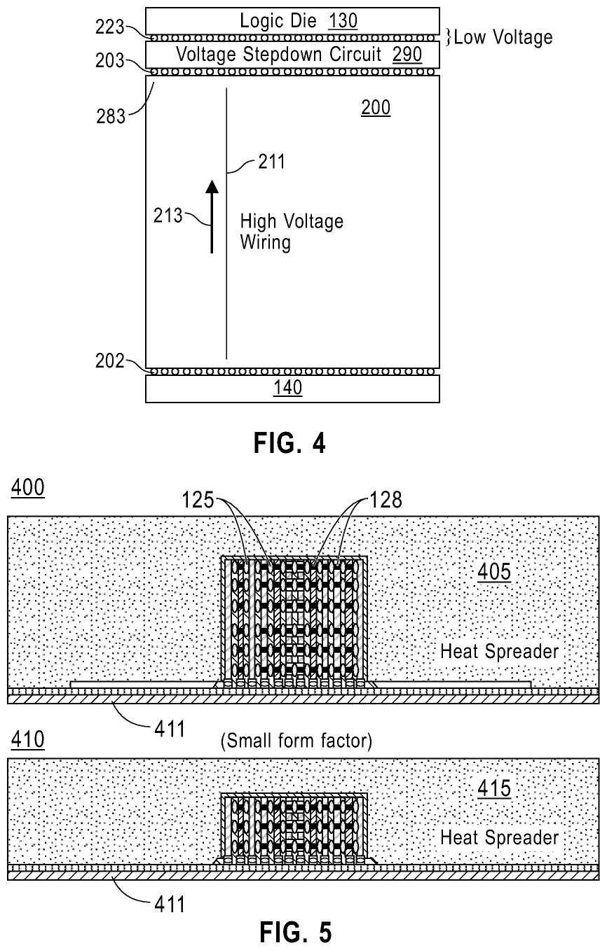

In view of FIG. 1, voltage power signals 13 are supplied to the bottom logic chip 40. Bottom logic chip 40 further supplies power signals 13 to top logic chip 30 via the bump 20 and corresponding metallurgy 25 and then carried by thin wire conductors in the chips 12 themselves. This flow of power signals through the chip wiring is subject to higher resistances which cause a voltage drop (e.g., a large IR drop) which reduces the power (P=I²R) received at the top logic chip 30 and potentially degrade performance as power consumption is increased. As a consequence, larger power voltages often need to be supplied. In an embodiment, to address this, reference is had to FIG. 2 which diagrammatically illustrates a 3D chip stack or 3D logic memory cube 100 according to an embodiment of the present disclosure.

In accordance with an embodiment of the present disclosure, FIG. 2 depicts a 3D high-bandwidth logic memory cube 100, the memory cube being provided with multiple separate chips or slices 125 having a substrate portion 126 (e.g., glass chip, dielectric oxide or active or passive Si-based chip) upon which is configured a memory chip(s) or a memory die 150. The memory cube 100 further includes “passive” slices 128 having a substrate portion 126 (e.g., glass chip, dielectric oxide or active or passive Si chips or slices) upon which is mounted on a surface thereof a fabricated “thick” metal wire 111. In an embodiment, thick metal wire 111 is a copper wiring dedicated for providing power signal routing to the memory die 150 and further power signal delivery from an electrically connected bottom logic circuit 140 to an electrically connected top logic circuit 130. In an embodiment, a “thick” conductor (metal) wiring is a wiring of a thickness of 1 μm or greater.

As shown in FIG. 2, the plurality of slices or chips 125 includes a memory die 150 including multiple memory chips (not shown) mounted thereon. In an embodiment, rather than a memory die, the one or more interspersed “passive” chips or slices 128 include a substrate 126 having a further mounted “dummy” mechanical die 180 (or a die with other active functions) and a mounted voltage step down circuit die 190. In an embodiment, the passive chips or slices 128 also include physical power lines, i.e., thick wires 111 fabricated on a substrate surface thereof, dedicated to deliver power signals, e.g., voltage, from the substrate or bottom logic die 140 to the memory circuitry of memory dies 150 and to the circuits of top logic die 130. In an embodiment, the voltage step down circuit die 190 provides power management features, e.g., circuitry for modifying one or more of: a voltage level, a current level or both a voltage and current level of a power signal received via the conductive thick wire 111. In an embodiment, voltage step down circuit die 190 performs a stepping down of a voltage and/or current of a received high voltage signal, to ensure correct power is routed from underlying substrate to the circuits of top logic die 130 for power management. The passive chip or a passive or active Si chip 128 can be further configured with de-coupling capacitors (decaps), inductors and/or voltage regulators for electrical power management. In an embodiment, the dimensions or size of the non-semiconductor passive chips 128, relative to the passive or active Si memory slices or chips 125, are different in the X-axis size or dimension and/or Y-axis size or dimension and/or Z-axis size or dimension.

As further shown in FIG. 2, in an embodiment, there is provided a 3D chip stack or 3D logic memory cube 100 consisting of a horizontally configured stack of multiple vertically-oriented chips or “slices” 125 disposed side-by-side, which are configured with a memory die 150, each memory die 150 having one or more memory chips with each chip having one or more levels of circuitry, e.g., memory cells, transistors, etc. The slice or chip 125 includes a non-semiconductor substrate 126, e.g., glass or a dielectric oxide material, or an active or passive Si-containing substrate portion. In embodiments, a memory slice or chip 125 includes a thick conductive wiring 111 extending from a bottom edge 182 to top edge 183 of the substrate 126. That is, each vertically-oriented non-semiconductor passive chip substrate 126 has an area for mounting of thick wiring 111 for more efficient high voltage power signal delivery. In an embodiment, the thickness of the glass, dielectric oxide material, or a Si-containing substrate portion 126 can range from a minimum of 10 microns in thickness or greater. In an embodiment, the 3D memory cube 100 is configurable as an alternating arrangement of vertically-oriented semiconductor memory slices 125 and vertically-oriented non-semiconductor passive slices 128, i.e., alternating semiconductor (or non-semiconductor) memory slices 125 and non-semiconductor (e.g., glass) slices 128 (e.g., Glass-Memory-Glass-Memory, etc.). Alternatively, as the passive slices 128 can have active or passive Silicon substrates 126 the alternating arrangement can be configured as memory slices 125 and Si passive slices 128 (e.g., Si-Memory-Si-Memory, etc.). Otherwise, to increase memory capacity, two or more memory slices 125 can be disposed adjacent each other and these between non-semiconductor (e.g., glass) slices 128 in the stack to form a stacked arrangement of, e.g., Glass-Memory-Memory-Glass-Memory-Memory-Glass, etc. Alternatively, as the passive slices 128 can have active or passive Silicon substrates 126 the stacked arrangement can be configured as, e.g., Si-Memory-Memory-Si-Memory-Memory-Si, etc.).

In an embodiment, the 3D logic memory cube 100 includes a top logic chip 130, e.g., containing switches and logic circuits that receive power signals to enable further processing of data input from and output to additional signal lines (not shown) connecting the memory dies or chips 150. The top logic chip 130 can include active devices, and the passive chips 125, 128 are vertically aligned such that a surface of the chips and memory dies is oriented perpendicular to the active device surface of the logic chip 130. A bottom element 140 is a further logic chip containing switches and logic circuits for input/output (I/O) routing of data from/to memory chips 150 or other circuitry (not shown), and for providing power signals to be routed to the respective vertically-oriented passive chips with memory die 150 and to top logic element 130 via dedicated copper wiring 111. In an embodiment, the bottom logic chip 140 can be formed on a substrate, interposer or like chip-carrier (not shown). For example, the multiple semiconductor vertically-oriented chips or slices (substrate) 125, 128 are provided with edge connections and adapted to be mounted to the logic chip 140 using known solder bump semiconductor chip packaging technology. In an embodiment, the substrate of each passive chip 125, 128 includes an edge connector at a bottom edge 182 including one or more conductors for electrically connecting a respective mounted thick copper wire 111 at one end to thereof to aligned metal structures, e.g., solder bumps 102, that connect a respective wire 111 to a power source (not shown) at the logic chip 140. Similarly, each passive chip 125, 128 includes an edge connector (not shown) at a top edge 183 including one or more respective conductors for electrically connecting the opposite end of the mounted thick wire 111 to an aligned metal structure, e.g., solder bump 103, that connect to an active device at the top logic chip 130.

FIG. 2A shows a cross-sectional view of a single passive chip 128 taken along line A-A of FIG. 2 and showing a configuration of the slice 128 along a Z-axis direction. The substrate 126 (e.g., glass chip, dielectric oxide or active or passive Si-based chip) of passive slice 128 includes mounted “thick conductive wires 111A, also referred to herein as “long distance”, i.e., high voltage, low current lines 111A, for carrying power signals from logic circuit 140 and/or from any substrate (not shown) directly to a conductive component of the voltage stepdown circuit die 190 that interfaces with circuitry for power management (e.g., voltage step-down) processing. The passive chip substrate 126 includes a further section mounting voltage stepdown die 190 that provides voltage converter or transformer network circuitry for processing received power signals from conductive wires 111A at connections 161 and providing a stepped-down voltage and/or current to the top logic die 130. In a non-limiting example, a high voltage, e.g., 3 V DC, carried by a thick “long distance” wire, can be stepped down to about 1 V for supply to the other components in the top logic chip 130. In an embodiment, step down circuitry can include a converter or step down transformer. If the logic die 130 requires different voltages, the voltage step down die 130 can have different step-down circuits to convert received voltages to different values, e.g., 0.9 V DC, 1.1 V DC, etc. The stepdown voltage signal from the voltage stepdown die 190 is then conveyed to the top logic die 130 via connections 162 along a respective “short distance”, i.e., low voltage, high current wire lines 111B. In an embodiment, a “long distance” wire line 111A ranges from between about 1 mm to 10 mm and a “short distance” wire line 111B is about ⅕ of the long distance wire length. In an embodiment, wires 111A, 111B is of a thickness of 100 microns. As shown in FIG. 2A, dummy mechanical die 180 includes interconnect locations 160 corresponding to conductive interconnect structures where power signals carried on long distance high voltage low current lines 111A connect via conductive interconnections (e.g., solder, copper) to memory chips on an adjacent passive chip 125 having a memory die 150.

As further shown in the cross-sectional view of FIG. 2A, the voltage step down die 190 on passive chip 128 can include a plurality of connectors 161 that receive power signals from long distance wires 111A and connect them to voltage step-down circuitry at die 190 and further connectors 162 that convey stepped-down voltage signals to the top logic die 130 via a respective short distance wires 111B. The voltage step down die 190 further includes a crackstop seal ring structure 121 designed to prevent crack propagation and provide a moisture oxidation barrier to reduce moisture ingression into the active die area and prevent cracking of any silicon. As further shown in the cross-sectional view of FIG. 2A, in an embodiment, the voltage step down die 190 on passive chip 128 can include a crackstop seal ring structure 121 designed to prevent crack propagation and provide a moisture oxidation barrier to reduce moisture ingression into the active die area and prevent cracking of any silicon. In other embodiments, the passive chips 125, 128 does not have crack stops, but can be sealed using sealing dielectric (SiO₂, SiN) to allow wiring 111 to go to the edge. Then under-bump metallurgy can be fabricated on the wiring edge.

FIG. 2B shows a cross-sectional view of the passive chip 125 taken along line B-B of FIG. 2 and showing a configuration of the slice 125 along a Z-axis direction. The passive chip 125 includes the memory die 150 for mechanically mounting memory chips (not shown) and providing conductive connections to top and bottom edge electrical connectors for interfacing with respective circuits at top logic die 130 and bottom logic die 140. As shown in FIG. 2B, directly connecting a metal structure 102 from an off-die input/output (I/O) connection at bottom edge 182 to a metal structure 103 at a top edge 183 that electrically connects to a device at the top logic die 130 is a mounted “long distance” wire 111. In an embodiment, this mounted wire 111 provides a direct I/O connection to top logic die 130 for receiving input signals from and/or outputting signals to an off-die device. Further as shown, at bottom edge 182, electrically connecting respective solder bump or like metal connect structures 102 interfacing with bottom logic die include respective long distance wires 151 which function as memory power lines that connect from bottom logic die 140 to mounted memory chips on memory die 150 via conductive connectors 155 that provide electrical connection to a memory chip device. In an embodiment, memory power lines 151 can be 100 microns thick. As shown in FIG. 2B, directly connecting a mounted memory chip(s) at memory die 150 to electrical connector at top edge 183 are respective short distance wires 152. These wires connect to a top edge connector (not shown) for aligned connection to a respective solder bump or like metal connect structure 103 at a top edge 183 that is in electrical connection to a device at the top logic die 130. In an embodiment, these short distance wires 152 provides physical low energy connections for providing data/address signals and other signals to/from top logic die 130 to a specific memory chip location.

As further shown in the cross-sectional view of FIG. 2B, the entire memory die 150 on passive chip 125 can include a crackstop seal ring structure 122 designed to prevent crack propagation and provide a moisture oxidation barrier to reduce moisture ingression into the active die area and prevent cracking of any silicon.

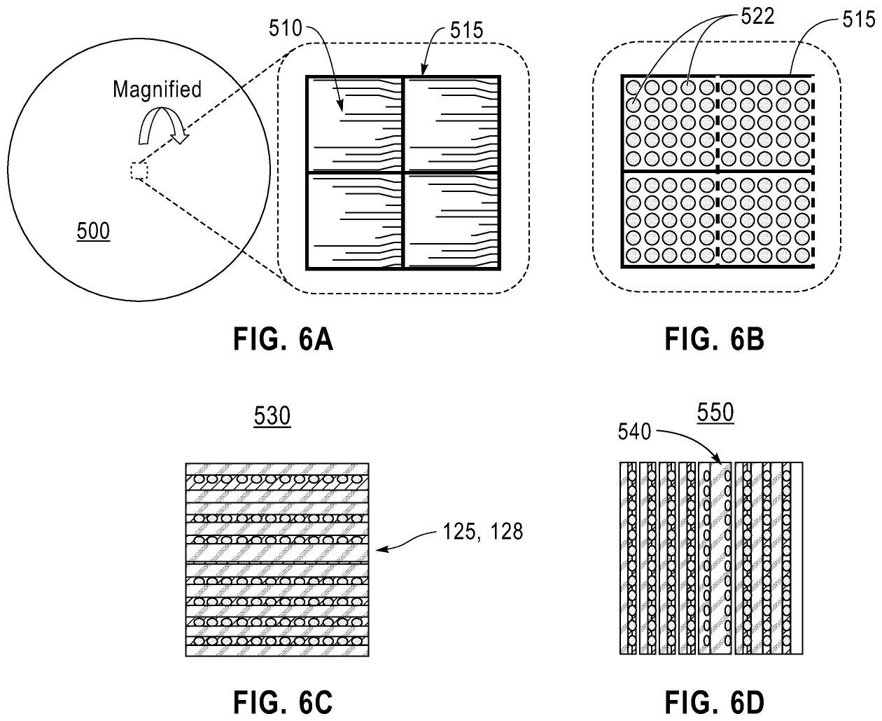

FIGS. 3A-3C depict more detailed cross-sectional views of an edge 300 of a non-semiconductor passive chip or a passive or active Si chip for power delivery according to an embodiment shown in FIG. 2. As shown in FIG. 3A, there is formed a resulting structure including a horizontally stack assembly including a passive chip substrate 326 (e.g., glass or dielectric oxide) for power delivery, a thick copper wiring metallization structure 311, a dielectric (e.g., SiO₂, SiN) layer 315 and a memory chip 350. As shown in FIG. 3A, each of the bottommost edges 320 of the assembly are not in alignment.

FIG. 3B depicts a cross-sectional of a resulting stacked assembly structure after a processing step of depositing a coating of a sealing dielectric material (e.g., SiO₂, SiN) 330 along the bottom edges 320 of the stack. In an embodiment, when the edge is sealed using sealing dielectric, the does not need crack stops.

FIG. 3C depicts a cross-sectional of a resulting stacked assembly structure after a processing step of planarizing the lateral surface of the sealing dielectric material along the bottom edges 320 of the stack to form a uniform bottom surface or edge 382 that exposes a bottom surface 325 of the copper wiring wire 311.

FIG. 3D depicts a cross-sectional of a resulting stacked assembly structure after a processing step of fabricating, using known semiconductor processing techniques, an under-bump metal (UBM) structure 340 connecting the bottom surface 325 of the planarized bottom edge of the copper wiring. Such UBM structure may comprise a conductive material such as Ti, Cu, Ni, Au, and the like.

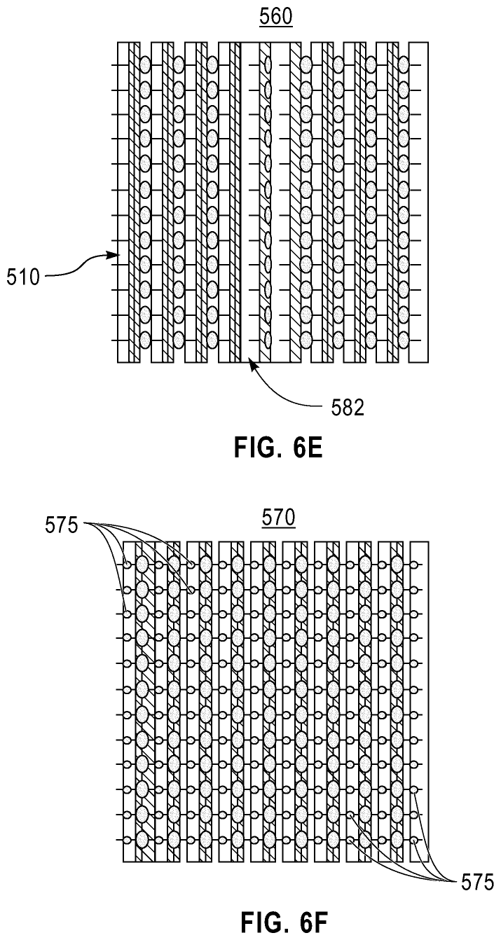

FIG. 4 shows an alternate embodiment of a single vertically-oriented memory chip or memory slice 200, e.g., a glass, an oxide or like dielectric material, or a silicon (passive or active) chip including thick wire conductor 211 connecting from bottom logic die 140 to an edge connector at a top edge 282 of the chip 200. In an embodiment, a power signal is delivered from bottom logic die 140 to the vertically-oriented chip or slice 200 via a respective conductive interconnection that can include a conductive bump/under-bump metallurgy 202. In the embodiment depicted, the top edge connector (not shown) connects a wire conductor to an input of a separate transverse-oriented voltage step down circuit chip 290 (i.e., transverse oriented relative to vertical-oriented slice) via a respective conductive interconnection that can include a conductive bump/under-bump metallurgy 203. The transverse-oriented voltage stepdown circuitry 290 converts (i.e., steps down) the received high voltage power signal 213 into a lower voltage and conveys this lower voltage to a top logic die 130. Lower voltage power signals are delivered from the transverse-oriented voltage stepdown circuitry 290 to the top logic die 130 via a respective conductive interconnection that can include a conductive bump/under-bump metallurgy 223.

In an alternative embodiment, as shown in FIG. 4, thin metallization wiring 211 (e.g., 10 microns or greater in thickness) in the memory chips of the slices 200 can be used for power delivery of high bandwidth memory cube and used with voltage step down circuit 290 at the top edge of themselves.

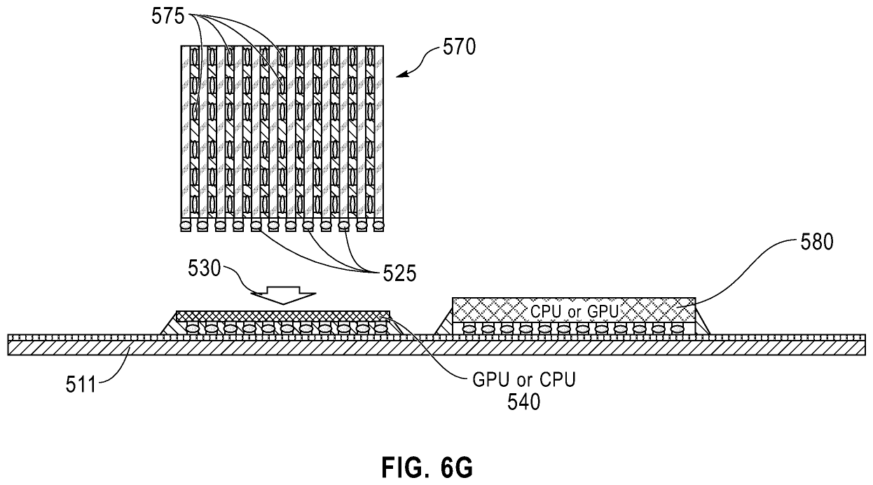

FIG. 5 shows a cross-sectional view of a first high bandwidth memory cube 400 for high-end servers and mobile/edge computing and other high-end applications and a high bandwidth memory cube 410 in a small form factor, e.g., a height of a small form factor high bandwidth memory cube is a few mm. For mobile applications/edge computing, the high bandwidth 3D memory cube itself includes the non-semiconductor passive chip or a passive or active Si slices 125, 128 for power delivery supported by a carrier or interposer 411 and also a heat spreader 405 formed surrounding the cube. Similarly, the high bandwidth memory cube 410 of small form factor itself includes the non-semiconductor passive chip or a passive or active Si structures for power delivery and also a heat spreader 415 formed on an carrier or interposer. In each embodiment, the non-semiconductor passive chip or a passive or active Si including structures working for power delivery enables customization of standard DRAM, fixed wiring, and fixed I/O footprint and further enables customization of low cost high volume products.

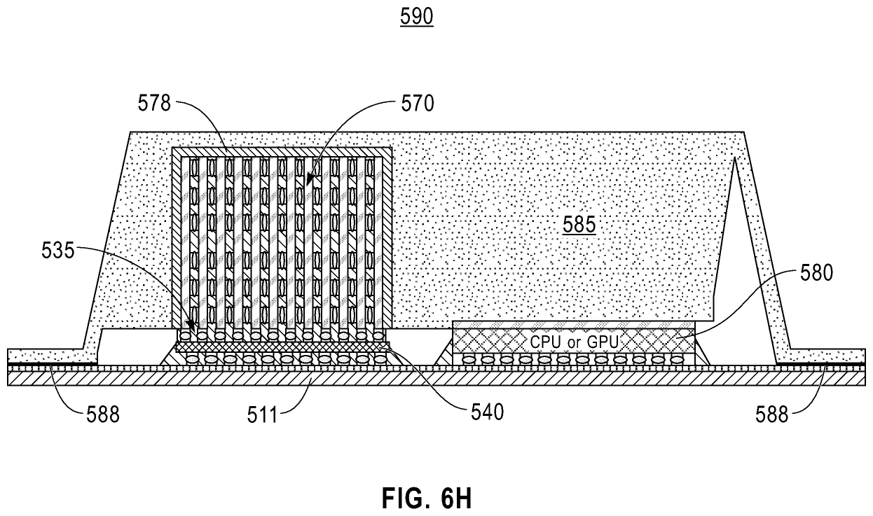

FIGS. 6A-6H depicts an exemplary process for fabricating a 3D high-bandwidth memory cube according to embodiments herein. As shown in FIG. 6A, there is depicted a memory wafer 500 having fabricated memory chips or memory devices, including but not limited to: dynamic random access memory (DRAM), eDRAM (embedded DRAM), and/or memory combined with logic devices. Additionally, included are the prepared logic, memory, Glass or Si (for power delivery) dies and voltage step down circuit dies. In a magnified view depicted in FIG. 6A, there is further depicted a fabricated redistribution layer (RDL) 510 which is a layer of wiring metal, e.g., Cu, interconnects that redistribute the I/O access to different parts of the chip and makes it easier to add microbumps to a die. The magnified view shown in FIG. 6A depicts four RDL sections, separated by a dicing line 515.

FIG. 6B shows a resulting structure 525 of each chip on the memory wafer 500 after fabricating metal interconnects, e.g., bumps 522, according to known under-bump metallurgy techniques in an embodiment.

FIG. 6C shows a resulting 3D high-bandwidth memory cube structure in the form of a stack 530 of horizontally disposed memory chips or memory slices 125 and including those passive slices 128 having mounted thick wires for routing power signals through the structure. The resulting formed stack of 3D high-bandwidth memory cube structure 530 are subject to hybrid bonding or thermal compression bonding (solder bonding), or a combination of both due to coefficient of thermal expansion-matched (CTE-matched) cube structure according to an embodiment.

FIG. 6D shows a resulting 3D high-bandwidth memory cube structure 550 after rotating the memory stack 530 of memory chips 125, 128 of FIG. 6C by 90° to vertically dispose the formed stack. Additionally, if needed, this structure can be fabricated with a sealed dielectric and planarized lateral surface 540 resulting from a performed chemical mechanical polishing (CMP) step.

FIG. 6E shows a resulting 3D high-bandwidth memory cube structure 560 after fabricating RDL on the planarized lateral surface of edge 582. The RDL 510 is connected with the RDL fabricated as shown in the processing step depicted in FIG. 6A.

FIG. 6F depicts a resulting 3D high-bandwidth memory cube structure 570 after forming under bump structures (interconnectors) 575 on the planarized lateral surfaces 540, for example by performing an electroplating or IMS (Injection Molded Soldering) step.

FIG. 6G depicts a processing step for bonding the 3D high-bandwidth memory cube structure 570 (e.g., by rotating 90 degree the structure of FIG. 6F) to a graphics processing unit (GPU) or central processing unit (CPU). In FIG. 5G, the 3D high-bandwidth memory cube structure 570 is disposed above and the under-bump structures 525 corresponding to under bump structures 575 are aligned at 530 with corresponding interconnect structures of an underlying logic unit 540, e.g., a GPU or CPU which is already formed mounted on and electrically connected an Si-interposer or substrate having one or more GPU/CPU 580 formed thereon. The aligned 3D memory cube structure 570 is then attached to the logic die, e.g., GPU or CPU 540.

FIG. 6H depicts a resulting processor apparatus 590 including the 3D high-bandwidth memory cube 570 after dispensing of an underfill material to bond the cube to the GPU/CPU logic die 540 and after attaching a heat spreader or heat sink structure 585. In particular, at an interface between the 3D memory cube structure 570 interconnects and the GPU/CPU logic die 540, an underfill material 535, e.g., SiO₂ and/or Al2O3, at one or more edges of the die for providing additional structural support. Further applied is a thermal interface material (TIM) layer 578, e.g., thermal paste or adhesive, around the 3D high-bandwidth memory cube structure 570 in order to enhance the thermal coupling between the cube structure and the formed heat spreader 585. The attached heat spreader 585 can be any tungsten- or molybdenum-based heat dissipating material known in the art and is formed to cover the TIM layer of the 3D high-bandwidth memory cube structure 570 and any other heat generating component, e.g., GPU or CPU 580 on the Si-interposer 511 and forms a seal with the interposer 511 using a sealband adhesive 588.

By implementing a glass chip or a Si chip with thick wiring and voltage step down circuitry in a memory cube structure, the power management challenges of 3D cube memory chips and their ready integration in a high-performance chiplet/3D memory strategy is solved. That is, advantageous use can be made of the high-bandwidth memory cube structure 100 for high performance chiplet/3D application strategies, e.g., supporting applications such as digital artificial intelligence (AI), analog AI, and other high performance computing applications.

Besides solving power management challenges, the non-semiconductor passive chips (e.g., glass chips, dielectric oxide chips) or Si chips with thick wiring used for power delivery enables customization of the memory, e.g., standard DRAM, fixed wiring, and fixed I/O footprint (e.g., for low cost, high volume products).

The high bandwidth memory cubes are in small form factor (smaller, thinner), e.g., 2-3 mm×2-3 mm, for use in mobile applications, edge computing and automotive applications. For example, in further embodiments, the non-semiconductor passive chips, or passive or active Si chips of for power delivery can be configured with (i.e., embedded or integrated) with antennas for mobile applications and edge computing. The self-contained functions (e.g., short vs. long distance wires) are consistent with energy efficient computing.

While the figures herein illustratively demonstrate exemplary structures and processing steps, according to specific embodiments of the present invention, it is clear that a person ordinarily skilled in the art can readily modify such structures or process steps for adaptation to specific application requirements, consistent with the above descriptions.

It should therefore be recognized that the present invention is not limited to the specific embodiment illustrated hereinabove, but rather extends in utility to any other modification, variation, application, and embodiment, and accordingly all such other modifications, variations, applications, and embodiments are to be regarded as being within the spirit and scope of the invention.

What is claimed is:

1. An apparatus comprising:
a plurality of vertically oriented semiconductor memory slices, each semiconductor memory slice having one or more memory elements disposed thereon for storing data;
one or more vertically oriented passive slices having a conductive wire element disposed thereon for delivering power signals from a power source, the plurality of vertically oriented semiconductor memory slices and one or more vertically oriented passive slices forming a stack; and
a logic chip disposed on top of the stack and oriented perpendicular to the plurality of vertically oriented semiconductor memory slices and one or more vertically oriented non-semiconductor passive slices, the logic chip having circuitry configured to process data from a semiconductor memory slice, wherein the wiring element delivers power signals to said logic chip circuitry.

2. The apparatus of claim 1, wherein said passive slices comprise a glass substrate or a dielectric oxide material substrate or a silicon-containing substrate with the thick wiring element for the power signal delivery.

3. The apparatus of claim 1, wherein a semiconductor memory slices comprises a passive or active silicon-based (Si) integrated circuit chip, the passive or active silicon-based integrated circuit chip having no crack stop structure.

4. The apparatus of claim 1, wherein the passive or active silicon-based (Si) integrated circuit chip is sealed using a sealing dielectric material.

5. The apparatus of claim 1, wherein the wiring element for delivering power extends from a conductive connection at a bottom edge of the passive slice to a conductive connection at a top edge of the passive slice.

6. The apparatus of claim 1, wherein the passive slice comprises:
a voltage step down circuit for modifying one or more of: a voltage level, a current level or both a voltage and current level of a received signal;
a first thick wire extending from the conductive connection at a bottom edge of the non-semiconductor passive slice to the voltage step down circuit for receipt of power signals thereat; and
a second shorter wire extending from the voltage step down circuit to a conductive connector at said logic chip for delivery of modified power signals.

7. The apparatus of claim 1, wherein the passive slice further comprises a dummy mechanical die or a die with other circuitry.

8. The apparatus of claim 1, wherein a size of the passive slice having the wiring element for delivering power signals is different in the X-axis dimension and/or Y-axis dimension and/or Z-axis dimension relative to a size of the semiconductor memory slices.

9. The apparatus of claim 1, wherein the non-semiconductor passive slice having the wiring element for delivering power signals further comprises one or more of embedded decoupling capacitors, inductors or voltage regulator devices.

10. The apparatus of claim 1, wherein each non-semiconductor passive slice comprises a planarized edge surface exposing a surface of the wiring element, the apparatus further comprising: an under-bump metal connection contacting the exposed surface of the wiring element.

11. The apparatus of claim 1, comprising an alternating arrangement of vertically-oriented semiconductor memory slices and vertically-oriented non-semiconductor passive slices having the wire element disposed thereon.

12. The apparatus of claim 1, further comprising:
a voltage step-down circuit disposed on top of the stack and beneath the logic chip, the voltage step-down circuit oriented perpendicular to the plurality of vertically-oriented semiconductor memory slices and having circuitry for receiving a power signal from a vertically-oriented semiconductor memory slice and modifying one of: voltage level, a current level or both a voltage and current level, of the received power signal.

13. The apparatus of claim 1, further comprising:
an interposer structure; and
a further logic chip formed on the interposer structure, wherein the formed stack of the plurality of vertically-oriented semiconductor memory slices and one or more vertically-oriented passive slices have bottom edge connectors electrically connecting to active devices of the further logic chip.

14. An apparatus comprising:
a stacked structure comprising a plurality of vertically oriented semiconductor memory slices, each semiconductor memory slice having one or more memory elements disposed thereon for storing data and a plurality of vertically oriented passive slices having a conductive wire element disposed thereon for delivering power signals from a power source;
a voltage step down chip disposed on top of the stack and oriented perpendicular to the plurality of vertically oriented semiconductor memory slices and vertically oriented non-semiconductor passive slices for modifying one or more of: a voltage level, a current level or both a voltage and current level of a power signal received via said conductive wire element signal; and
a logic chip disposed on top of the voltage step down chip and in electrical communication therewith and having circuitry configured to process data from a semiconductor memory slice, wherein the wiring element delivers modified power signals to said logic chip circuitry.

15. The apparatus of claim 15, wherein said passive slices comprise a glass substrate or a dielectric oxide material substrate or a silicon-containing substrate with the thick wiring element for the power signal delivery.

16. The apparatus of claim 15, wherein a semiconductor memory slices comprises a passive or active silicon-based (Si) integrated circuit chip, the passive or active silicon-based integrated circuit chip having no crack stop structure.

17. The apparatus of claim 15, wherein the wire element for delivering power extends from a conductive connection at a bottom edge of the passive slice to a conductive connection at a top edge of the passive slice.

18. The apparatus of claim 13, further comprising:
an interposer structure, where the voltage step down chip is disposed on said interposer structure.

19. A method of forming a stacked memory structure comprising:
providing one or more active or passive substrates having a memory die formed thereon;
providing one or more passive substrates having a wire element formed thereon, said wire element extending from a bottom edge to a top edge of said passive substrate for delivering power signals;
stacking an arrangement of said active or passive substrates having a memory die thereon and passive substrates having a wire element formed thereon;
bonding said stacked arrangement of substrates and dies by hybrid bonding or thermal compression bonding;
planarizing a lateral surface of stacked dies;
forming under-bump metallization on said planarized lateral surface in alignment with an edge of said wire element;
bonding said stacked bonded stacked arrangement of substrates and dies to a substrate; and
dispensing an underfill material for packaging said stacked memory structure.

20. The method of claim 19, further comprising:
attaching a heat spreader to surround portions of said stacked bonded stacked arrangement of substrates and dies.
